(19) United States
(12) Patent Application Publication
(10) Pub. No.: US 2015/0380498 A1
(43) Pub. Date: Dec. 31, 2015

(54) METHOD FOR PRODUCING A SEMICONDUCTOR DEVICE, AND SEMICONDUCTOR DEVICE PRODUCED THEREBY

(71) Applicant: FUJI ELECTRIC CO., LTD., Kawasaki-shi (JP)

(72) Inventors: Ryo TANAKA, Santa Barbara, CA (US); Shinya TAKASHIMA, Tokyo (JP); Katsunori UENO, Matsumoto City (JP); Masaharu EDO, Tokorozawa City (JP)

(73) Assignee: FUJI ELECTRIC CO., LTD., Kawasaki-shi (JP)

(21) Appl. No.: 14/848,889

(22) Filed: Sep. 9, 2015

Related U.S. Application Data
(63) Continuation of application No. PCT/JP2014/067226, filed on Jun. 27, 2014.

(30) Foreign Application Priority Data
Aug. 27, 2013 (JP) 2013-176006

(51) Int. Cl. H01L 29/20; H01L 29/205; H01L 21/306; H01L 21/324; H01L 29/207; H01L 21/02; H01L 21/265

(52) U.S. Cl. CPC H01L 29/2003; H01L 21/0254; H01L 29/205; H01L 21/26546; H01L 21/324; H01L 21/02389; H01L 21/0262; H01L 29/207; H01L 21/30612; H01L 21/30621

(57) ABSTRACT

A method for producing a semiconductor device having a nitride-based semiconductor layer includes forming a first nitride-based semiconductor layer of AlₓGa₁₋ₓN on a base; forming a second nitride-based semiconductor layer of Al_{y}Ga_{1-y}N on the first nitride-based semiconductor layer; forming a third nitride-based semiconductor layer of Al_{z}Ga_{1-z}N on the second nitride-based semiconductor layer; introducing an impurity using ion implantation into the first, second, and third nitride-based semiconductor layers; and thermally treating, after ion implantation, the first, second, and third nitride-based semiconductor layers, wherein the first, second, and third nitride-based semiconductor layers have respective Al composition ratios x, y, and z, and the Al composition ratio y of the second nitride-based semiconductor layer is higher than the Al composition ratio x of the first nitride-based semiconductor layer, and higher than the Al composition ratio z of the third nitride-based semiconductor layer.

### CROSS-REFERENCE TO RELATED APPLICATIONS

This non-provisional Application for a U.S. Patent is a Continuation of International Application PCT/JP2014/067226 filed Jun. 27, 2014, which claims priority from JP PA 2013-176006 filed Aug. 27, 2013, the entire contents of both of which are hereby incorporated by reference.

### BACKGROUND OF THE INVENTION

1. Field of the Invention

The present invention relates to a method for producing a semiconductor device having a thermal treatment step, and to a semiconductor device.

2. Background of the Related Art

The field of power semiconductor devices has witnessed, in recent years, active development and research of products, that utilize wide band gap semiconductors such as nitride-based semiconductors, for instance gallium nitride (GaN)-based semiconductors, and the semiconductor devices have already begun to be put into practical use. As is known, wide band gap semiconductors are advantageous, as compared with conventionally used silicon (Si), in that the former allows producing high-breakdown voltage semiconductor devices with low on-resistance, and enable operation at high temperatures. By virtue of such advantages, nitride-based semiconductors are expected to replace Si-based materials, as materials of power devices such as inverters and converters.

A thermal treatment i.e. activation annealing at a high temperature, for crystal recovery and/or impurity activation, has to be performed after ion implantation in the production process of a nitride-based semiconductor device that is produced using a nitride-based semiconductor. However, when the activation annealing of a nitride-based semiconductor such as a GaN-based semiconductor reaches a heating temperature of 800° C. or higher, so-called nitrogen loss occurs and decomposing of nitride-based semiconductor starts by that nitrogen (N) which is a component of the nitride-based semiconductor escapes from the nitride-based semiconductor.

Known conventional methods aimed at countering this occurrence involve performing activation annealing after formation of a protective film (cap layer) comprising a material of higher heat resistance, on the upper layer of the nitride-based semiconductor layer by sputtering method. Japanese Patent Application Publication No. H08-186332 (Patent literature 1), Japanese Patent No. 2540791 (Patent literature 2), and J. C. Zolper et al., “Sputtered AlN encapsulant for high-temperature of GaN”, Appl. Phys. Lett. 69(4), 22 Jul. 1996 pp. 538-540 (Non-patent literature 1) disclose methods that involve performing a thermal treatment in nitrogen while protecting the surface using an AlN layer as a protective film.

Activation annealing after impurity doping, for instance by ion implantation, requires heating at a temperature that is about ⅔ of the melting point of the material that makes up the semiconductor layer. Specifically, a heating temperature ranging from about 1500° C. to 1700° C. is envisaged in a case where a nitride-based semiconductor such as GaN is used as the semiconductor material.

It has been reported, for instance by, X. A. Cao et al., “Ultrahigh Si+ implant activation efficiency in GaN using a high-temperature rapid thermal process system”, APPLIED PHYSICS LETTERS 73 (1998) pp. 229-231 (Non-patent literature 2) and by K. A. Jones et al., “The Properties of Annealed AlN Films Deposited by Pulsed Laser Deposition”, Journal of ELECTRONIC MATERIALS, Vol. 29, No. 3 2000 pp. 262-267 (Non-patent literature 3), that even when using an AlN layer as a protective film, however, pits may occur in the AlN layer, or the AlN layer may decompose, at such high-temperature regions, so that, as a result, the AlN layer no longer function as a protective film. For instance, Non-patent literature 2 reports the occurrence of pits in an AlN layer due to heating at a temperature of 1400° C. or higher, as an example where heating is performed at a temperature up to 1500° C. as a high-temperature region. When pits occur in the AlN layer that is used as a protective film during the thermal treatment, the occurrence of release, through the pits, of nitrogen that makes up the underlying nitride-based semiconductor layer increases.

Further, it has been difficult to suppress nitrogen loss from an underlying nitride-based semiconductor layer during the thermal treatment in high-temperature activation annealing, even when using a nitride-based semiconductor layer, such as an AlN layer formed by sputtering, as an overlying protective film of the nitride-based semiconductor layer. Findings by the inventors have revealed that the above occurrence arises from the coarse quality of the nitride-based semiconductor layer that is formed by sputtering. Therefore, the inventors have envisaged a method of suppressing nitrogen loss by forming a protective film that is imparted with a denser film quality through epitaxial growth.

However, when forming a nitride-based semiconductor layer, such as an AlN layer, as a protective film on top of a nitride-based semiconductor layer while making the quality of the layer denser through epitaxially growth, cracks might occur, in cases of large thickness of the layer being grown. Accordingly, the thickness of the protective film has been limited, at most, from about 4 nm to about 10 nm, and thus only a thin protective film could be formed, and a nitrogen loss suppressing effect failed to be achieved in some instances.

Such being the case, the temperature of activation annealing in the related art has been limited to about 1300° C. In a case where activation annealing is performed after impurity doping, for instance by ion implantation or the like, it is however difficult to elicit sufficient impurity activation and crystallinity recovery, in a semiconductor layer, at a heating temperature of about 1300° C. The problem of, for instance, lowered carrier mobility in the semiconductor device that is produced arises as a result in re related art. A further problem is that, in particular in a case where a p-type region is formed by ion implantation, it has not been possible to obtain a sufficient p-type carrier concentration for the amount of implanted impurity, due to the n-type carrier compensating effect elicited by defects.

In view of the above, it is an object of the present invention to provide a method for producing a semiconductor device and a semiconductor device that allow a high-temperature thermal treatment to be carried out stably and effectively, while preventing nitrogen loss from a nitride-based semiconductor layer that makes up a semiconductor device.

### SUMMARY OF THE INVENTION

In order to solve the above problems and attain the above goal, the method for producing a semiconductor device according to the present invention is a method for producing a semiconductor device having a nitride-based semiconductor layer, the method including: a first formation step of forming a first nitride-based semiconductor layer of AlₓGa₁₋ₓN on a base; a second formation step of forming a second nitride-based semiconductor layer of Al_{y}Ga_{1-y}N on the first nitride-based semiconductor layer; a third formation step of forming a third nitride-based semiconductor layer of Al_{z}Ga_{1-z}N on the second nitride-based semiconductor layer; an ion implantation step of introducing an impurity, on the basis of an ion implantation method, into the first nitride-based semiconductor layer, the second nitride-based semiconductor layer and the third nitride-based semiconductor layer; and a thermal treatment step of, after the ion implantation step, performing a thermal treatment on the first nitride-based semiconductor layer, the second nitride-based semiconductor layer and the third nitride-based semiconductor layer, wherein the Al composition ratio y of the second nitride-based semiconductor layer is higher than the Al composition ratio x of the first nitride-based semiconductor layer, and higher than the Al composition ratio z of the third nitride-based semiconductor layer.

The method for producing a semiconductor device according to the present invention is characterized in that in the above invention, the first nitride-based semiconductor layer is AlₓGa₁₋ₓN (0≦x<0.5). The method for producing a semiconductor device according to the present invention is characterized in that in the above configuration, the first nitride-based semiconductor layer is AlₓGa₁₋ₓN (0≦x<0.2).

The method for producing a semiconductor device according to the present invention is characterized in that in the above invention, the second nitride-based semiconductor layer is Al_{y}Ga_{1-y}N (0.5≦y≦1). The method for producing a semiconductor device according to the present invention is characterized in that in the above configuration, the second nitride-based semiconductor layer is Al_{y}Ga_{1-y}N (0.8≦y≦1).

The method for producing a semiconductor device according to the present invention is characterized in that in the above invention, the third nitride-based semiconductor layer is Al_{z}Ga_{1-z}N (0≦z<0.5). The method for producing a semiconductor device according to the present invention is characterized in that in the above configuration, the third nitride-based semiconductor layer is Al_{z}Ga_{1-z}N (0≦z<0.2).

The method for producing a semiconductor device according to the present invention is characterized in that in the above invention, the base has a substrate formed of gallium nitride.

The method for producing a semiconductor device according to the present invention is characterized in that in the above invention, the thickness of the third nitride-based semiconductor layer is greater than the thickness of the second nitride-based semiconductor layer.

The method for producing a semiconductor device according to the present invention is characterized in that in the above invention, the thickness of the second nitride-based semiconductor layer is greater than a critical thickness of the second nitride-based semiconductor.

The method for producing a semiconductor device according to the present invention is characterized in that in the above invention, the thickness of the third nitride-based semiconductor layer is 50 nm or greater.

The method for producing a semiconductor device according to the present invention is characterized in that in the above invention, the first nitride-based semiconductor layer, the second nitride-based semiconductor layer and the third nitride-based semiconductor layer are formed by metal-organic chemical vapor deposition.

The method for producing a semiconductor device according to the present invention is characterized in that in the above invention, the impurity introduced by the ion implantation step includes at least one element selected from the group consisting of magnesium, zinc and beryllium.

The method for producing a semiconductor device according to the present invention is characterized in that in the above invention, a thermal treatment temperature in the thermal treatment ranges from 800° C. to 2000° C.

The method for producing a semiconductor device according to the present invention is characterized in that the above invention further comprises a removal step of, after the thermal treatment step, removing at least part of the second nitride-based semiconductor layer and the third nitride-based semiconductor layer. The method for producing a semiconductor device according to the present invention is characterized in that in the removal step, the second nitride-based semiconductor layer is removed by wet etching. The method for producing a semiconductor device according to the present invention is characterized in that in the removal step, the third nitride-based semiconductor layer is removed by dry etching.

The semiconductor device according to the present invention is characterized by being produced in accordance with the method for producing a semiconductor device according to the above invention.

The method for producing a semiconductor device and semiconductor device according to the present invention allow performing, stably and effectively, a thermal treatment at a high temperature, while preventing nitrogen loss from a nitride-based semiconductor layer.

### BRIEF DESCRIPTION OF THE DRAWINGS

FIG. 1 is a cross-sectional diagram illustrating a semiconductor device according to Embodiment 1 of the present invention;

FIG. 2 is a schematic diagram for explaining a thermal treatment method according to Embodiment 1 of the present invention;

FIG. 3 is a schematic diagram for explaining a thermal treatment method according to Embodiment 1 of the present invention;

FIG. 4 is a schematic diagram for explaining a thermal treatment method according to Embodiment 1 of the present invention;

FIG. 5 is a schematic diagram for explaining a thermal treatment method according to Embodiment 1 of the present invention; and

FIG. 6 is a cross-sectional diagram of a substrate to be processed, for explaining a method for producing a semiconductor device according to Embodiment 2 of the present invention.

### DETAILED DESCRIPTION OF THE INVENTION

Embodiments of the present invention will be explained next with reference to accompanying drawings. The present invention is however not limited to or by the embodiments. In the figures, identical or corresponding elements are denoted, as appropriate, by identical reference symbols. The figures are schematic, and it should thus be noted that relationships and so forth between the dimensions of the various elements may differ from those of actual elements. The figures may also include portions of mutually different dimensional relationships or ratios between the figures.

### Embodiment 1

### Semiconductor Device

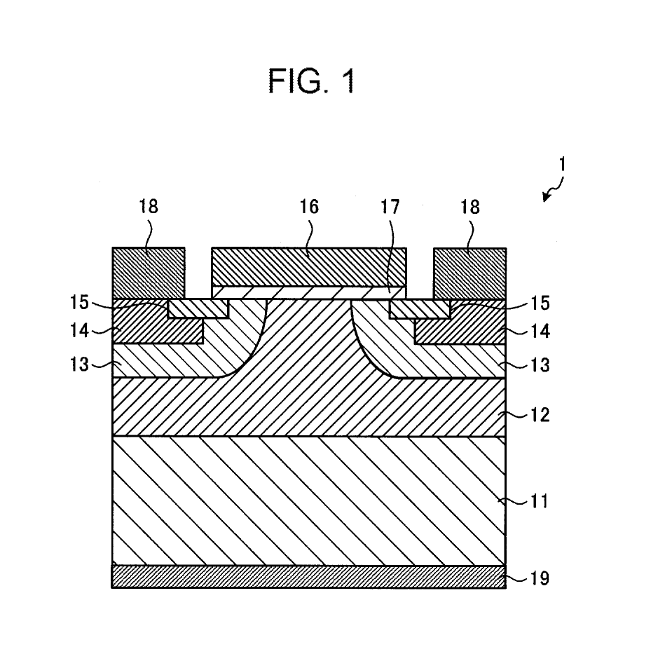

A semiconductor device according to Embodiment 1 of the present invention will be explained first. FIG. 1 is a cross-sectional diagram illustrating the configuration of a vertical-type MOSFET, as a semiconductor device of Embodiment 1. As illustrated in FIG. 1, the semiconductor device 1 of Embodiment 1 comprises an n-type gallium nitride (n-GaN) substrate 11 doped with an n-type impurity, and an n-AlₓGa₁₋ₓN layer 12, formed on the n-GaN substrate 11 for instance by epitaxial growth, as a first nitride-based semiconductor layer doped with an n-type impurity. The impurity concentration of the n-AlₓGa₁₋ₓN layer 12 is preferably lower than that of the n-GaN substrate 11. The Al composition of the n-AlₓGa₁₋ₓN layer 12 ranges typically from 0 to less than 0.5 (0≦x<0.5), and preferably from 0 to less than 0.2 (0≦x<0.2). In Embodiment 1, specifically, the n-AlₓGa₁₋ₓN layer 12 is for instance an n-GaN layer.

In the n-AlₓGa₁₋ₓN layer 12 there are formed a p-type well region 13 selectively doped with a p-type impurity, a p⁺-type well region 14 selectively doped with a p-type impurity, to a higher concentration than that in the p-type well region 13, and a n⁺-type source region 15 selectively doped with an n-type impurity, at a portion between the p-type well region 13 and the p⁺-type well region 14.

A gate electrode 16 is provided between a pair of p-type well regions 13, at a portion on the surface of the n-AlₓGa₁₋ₓN layer 12. The gate electrode 16 is provided, on the surface of the n-AlₓGa₁₋ₓN layer 12, via a gate insulating film 17 made up of an insulator such as silicon oxide (SiO₂), at the bottom face of the gate electrode 16. A pair of source electrodes 18 is provided, on the n-AlₓGa₁₋ₓN layer 12, so as to flank the gate electrode 16 and the gate insulating film 17 while spaced therefrom. A drain electrode 19 is provided on the rear surface of the n-GaN substrate 11. By virtue of the above configuration, a channel is formed in the semiconductor device 1, during driving of the latter, from the upper-layer p-type well region 13 over to the n-GaN substrate 11.

### Method for Producing a Semiconductor Device

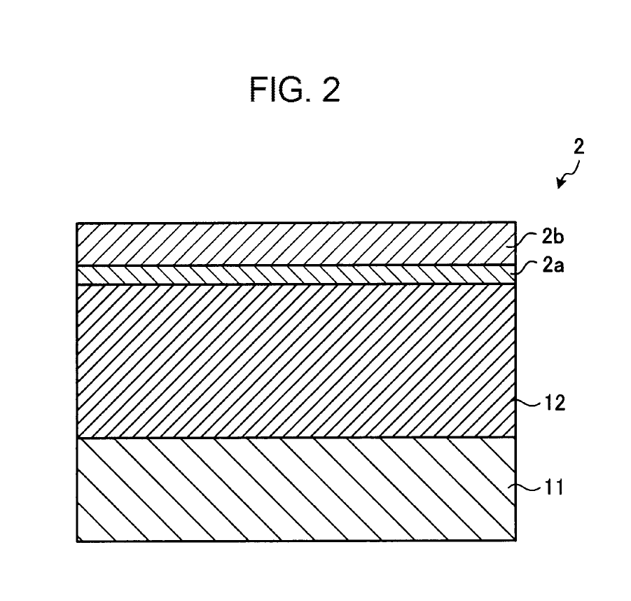

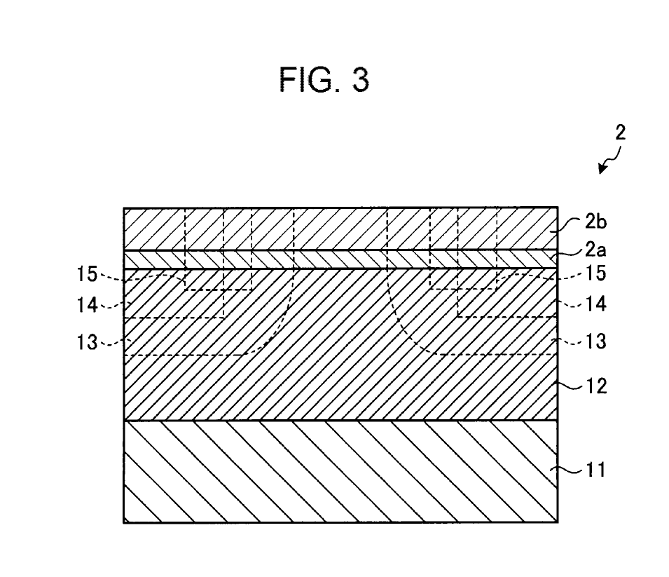

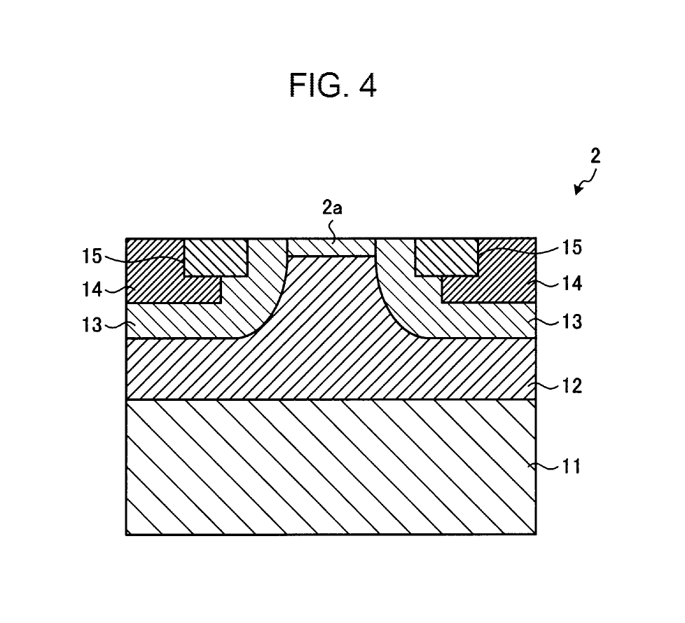

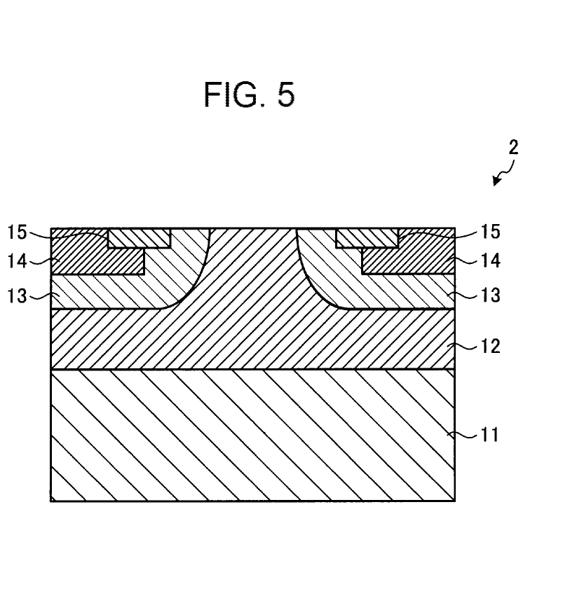

A method for producing the semiconductor device 1 according to Embodiment 1 having the above configuration will be explained next. FIG. 2, FIG. 3, FIG. 4 and FIG. 5 are schematic diagrams of a substrate to be processed, for explaining the method for producing the semiconductor device 1 according to Embodiment 1.

As illustrated in FIG. 2, specifically, AlₓGa₁₋ₓN is grown first, for instance by metal-organic chemical vapor deposition (MOCVD), on the n-GaN substrate 11, as a base, while doping the n-AlₓGa₁₋ₓN with an n-type impurity, to form as a result the n-AlₓGa₁₋ₓN layer 12, which is, for instance, an n-GaN layer. A sapphire substrate, a SiC substrate or the like may be used instead of the n-GaN substrate 11. The n-AlₓGa₁₋ₓN layer 12 may be grown by halide vapor phase growth (HVPE) or molecular beam epitaxy (MBE), instead of MOCVD.

Next, a first cap layer 2a, as a second nitride-based semiconductor layer, and a second cap layer 2b, as a third nitride-based semiconductor layer, are sequentially formed on the n-AlₓGa₁₋ₓN layer 12. Materials that are suitable for a subsequent thermal treatment step are selected herein as the materials of the first cap layer 2a and the second cap layer 2b that protect the surface of the n-AlₓGa₁₋ₓN layer 12.

Specifically, the material of the first cap layer 2a is preferably a material having a higher heat resistance than that of the underlying n-AlₓGa₁₋ₓN layer 12, and having good adhesion with the n-AlₓGa₁₋ₓN layer 12, such that the first cap layer 2a does not peel during a thermal treatment, and is moreover a dense material which does not react readily with the n-AlₓGa₁₋ₓN layer 12, and into which impurities do not diffuse readily. Therefore, Al_{y}Ga_{1-y}N having the Al composition ratio y higher than the Al composition ratio x of the underlying n-AlₓGa₁₋ₓN layer 12 is preferably used as the material that makes up the first cap layer 2a in Embodiment 1. In this case, the lattice constant of the material that makes up the first cap layer 2a is smaller than the lattice constant of the material that makes up the underlying n-AlₓGa₁₋ₓN layer 12. The Al composition ratio y ranges typically from 0.5 to 1 (0.5≦y≦1), and ranges preferably from 0.8 to 1 (0.8≦y≦1). In Embodiment 1, for instance, aluminum nitride (AlN) having the Al composition ratio y set to 1 is used as the material of the first cap layer 2a. Configuring the first cap layer 2a out of AlN is preferable in a case where the underlying layer is a GaN layer, since etching selectively can thus be increased, and hence the first cap layer 2a can be selectively removed with ease.

In terms of making the first cap layer 2a a dense layer so as to obtain a more pronounced surface protective effect, the first cap layer 2a is preferably formed by epitaxial growth, for instance by MOCVD, HVPE, MBE or the like. In Embodiment 1, therefore, the first cap layer 2a is formed, for instance by MOCVD, as a protective film comprising an Al_{y}Ga_{1-y}N layer on the surface of the n-AlₓGa₁₋ₓN layer 12. To form the first cap layer 2a by MOCVD, for instance a mixed gas is used that comprises ammonia (NH₃) gas and at least one starting gas from among an Al starting gas (trimethyl aluminum; TMA; Al(CH₃)₃)) and a Ga starting gas (trimethyl gallium; TMGa; Ga(CH₃)₃). The heating temperature during formation of the first cap layer 2a is preferably a temperature lower than the thermal treatment temperature (heating temperature) in the activation annealing that is performed thereafter, and ranges specifically, for instance, from 800° C. to 1200° C., while the atmosphere pressure ranges for instance from 5 kPa to 20 kPa. Preferably, the thickness of the first cap layer 2a is a thickness that allows suppressing nitrogen loss from the underlying n-AlₓGa₁₋ₓN layer 12 in the activation annealing that is performed thereafter. Specifically, the thickness of the first cap layer 2a is greater than a room-temperature critical thickness of an instance of a single layer in which the second cap layer 2b is not formed. In a case where the second cap layer 2b is configured as a GaN layer, and the first cap layer 2a is configured as a AlN layer, as described below, then the thickness of the first cap layer 2a is specifically 15 nm or greater, preferably 30 nm or greater.

The material of the second cap layer 2b is preferably a material that elicits relief of strain through suppression of stress generated in the first cap layer 2a, which is prone to cracking, and also a material that allows forming a thicker first cap layer 2a as compared with an instance where no second cap layer 2b is formed, and that exhibits good adhesion, such that the second cap layer 2b does not peel off during a high-temperature thermal treatment. Therefore, Al_{z}Ga_{1-z}N, having the Al composition ratio z smaller than the Al composition ratio y of the Al_{y}Ga_{1-y}N layer that makes up the underlying first cap layer 2a is used in Embodiment 1 as the material that makes up the second cap layer 2b. Strain in the first cap layer 2a is relieved as a result, since the lattice constant of the material that makes up the second cap layer 2b is greater than the lattice constant of the material that makes up the first cap layer 2a. The Al composition ratio z ranges typically from 0 to less than 0.5 (0≦z<0.5), and ranges preferably from 0 to less than 0.2 (0≦z<0.2).

In Embodiment 1, GaN having the Al composition ratio z set to 0 is used as the material of the second cap layer 2b. In terms of suppressing the occurrence of stress in the first cap layer 2a, the Al_{z}Ga_{1-z}N that makes up the second cap layer 2b has a composition identical (x=z) or similar (x≅z) to that of the n-AlₓGa₁₋ₓN layer 12.

Preferably, the second cap layer 2b is formed by epitaxial growth, for instance MOCVD, HVPE or MBE, in terms of achieving a dense film that affords a protective effect towards the first cap layer 2a. In Embodiment 1, therefore, the second cap layer 2b comprising an Al_{z}Ga_{1-z}N layer is formed, for instance by MOCVD, on the first cap layer 2a. To form the second cap layer 2b by MOCVD, for instance a mixed gas is used that comprises ammonia (NH₃) gas and at least one starting gas from among an Al starting gas (trimethyl aluminum; TMA; Al(CH₃)₃)), and a Ga starting gas (trimethyl gallium; TMGa; Ga(CH₃)₃). The heating temperature during formation of the second cap layer 2b is preferably a temperature lower than the thermal treatment temperature (heating temperature) in the activation annealing that is performed thereafter, and ranges specifically, for instance, from 800° C. to 1200° C., while the atmosphere pressure ranges for instance from 20 kPa to 50 kPa. Preferably, the thickness of the second cap layer 2b is equal to or greater than a thickness such that strain can be relieved, by suppressing the occurrence of stress in the first cap layer 2a, and such that the second cap layer 2b is left standing as a result of activation annealing that is performed thereafter. Preferably, the thickness of the second cap layer 2b is set to be greater than the thickness of the first cap layer 2a, specifically, for instance, is set to be 50 nm or greater, in terms of further protecting the first cap layer 2a.

Next, as illustrated in FIG. 3, a p-type impurity is selectively and sequentially ion-implanted into the stacked film made up of the n-AlₓGa₁₋ₓN layer 12, the first cap layer 2a and the second cap layer 2b, at regions at which the p-type well region 13 and the p⁺-type well region 14 of high impurity concentration are to be formed, in accordance with an ion implantation method using a mask in the form of, for instance, silicon oxide (SiO₂) or a resist. As the p-type impurity there is used at least one element selected from the group consisting of magnesium (Mg), beryllium (Be) and zinc (Zn). Similarly, an n-type impurity such as silicon (Si) is selectively ion-implanted thereafter, in accordance with an ion implantation method, at a region of the portion of the p-type well region 13 and the p⁺-type well region 14 at which the n⁺-type source region 15 is to be formed. The energy in the ion implantation method is adjusted, as appropriate, to a value that allows a predetermined impurity to pass through the second cap layer 2b and the first cap layer 2a, and be introduced down to a desired depth in the n-AlₓGa₁₋ₓN layer 12.

A substrate to be processed 2 is thus obtained as a result. The first cap layer 2a and the second cap layer 2b obtained are formed through epitaxial growth of a nitride-based semiconductor crystal. Therefore, the cap layers have good crystallinity, and can be appropriately used as protective films for activation annealing.

Next there is performed a thermal treatment step of heating the substrate to be processed 2, specifically activation annealing is performed as a high-temperature thermal treatment for activating impurities comprised in the substrate to be processed 2. Activation annealing is a high-temperature thermal treatment in which the heating temperature is for instance 800° C. or higher, preferably 1200° C. or higher, and yet more preferably 1500° C. or higher, with an upper limit set to 2000° C. Securing the surface protective effect elicited by the first cap layer 2a and the second cap layer 2b is effective herein in a case where the thermal treatment temperature is 800° C. or higher, since decomposition of the n-AlₓGa₁₋ₓN layer 12 starts at such a temperature. Preferably, the pressure inside the thermal treatment apparatus in which the substrate to be processed 2 is placed is set to a range of, for instance, 0.1 MPa to 1000 MPa (1 atmosphere to 10000 atmospheres). The various impurities, Mg, Be, Zn and so forth with which the n-AlₓGa₁₋ₓN layer 12 is doped are activated as a result of the activation annealing, whereupon the p-type well region 13, the p⁺-type well region 14 and the n⁺-type source region 15 are accordingly formed.

Thereafter, as illustrated in FIG. 4, at least part and preferably the entirety of the second cap layer 2b is removed by dry etching using for instance a chlorine-based gas. In a case where part of the second cap layer 2b is removed, a mask (not shown) is formed on the second cap layer 2b, by resorting for instance to a photolithographic process, and dry etching is performed using the mask as an etching mask.

Next, at least part, and preferably the entirety, of the first cap layer 2a is removed from the substrate to be processed 2, as illustrated in FIG. 5, by wet etching using a solution having high etching selectively between AlₓGa₁₋ₓN and Al_{y}Ga_{1-y}N. In a case where part of the first cap layer 2a is removed, for instance a mask (not shown) may be formed on at least one from among the first cap layer 2a and the second cap layer 2b, by resorting to a photolithographic process, followed by etching using that mask as an a etching mask; alternatively, the second cap layer 2b may be used as a mask. In a case where the n-AlₓGa₁₋ₓN layer 12 is made up of n-GaN and the first cap layer 2a made up of AlN, high etching selectively can be secured by using an aqueous solution of potassium hydroxide (KOH).

Next, the gate insulating film 17 comprising, for instance, a SiO₂ film, is grown, for instance by PECVD (Plasma Enhanced CVD), on the top face of the n-AlₓGa₁₋ₓN layer 12. The thickness of the gate insulating film 17 is for instance about 100 nm. Other than an SiO₂ film, the gate insulating film 17 may be an insulating film in the form of a SiNₓ film, a SiON film, an Al₂O₃ film, a MgO film, a GaOₓ film, a GdOₓ film or the like, or a stacked film comprising any one of the foregoing.

Next, a polycrystalline silicon film is formed, for instance by LPCVD (low pressure chemical vapor deposition), on the gate insulating film 17, with an n-type impurity such as phosphorus (P) or arsenic (As) being doped after or during formation of the polycrystalline silicon film. The polycrystalline silicon film exhibits conductivity as a result. Doping of the polycrystalline silicon film with an n-type impurity can be accomplished through ion implantation of the n-type impurity after formation of the polycrystalline silicon film, or by introducing the n-type impurity during growth of the polycrystalline silicon film. As a result of the thermal treatment, the doping n-type impurity is activated and diffuses into the polycrystalline silicon film.

Next, the polycrystalline silicon film and the gate insulating film 17 are patterned according to a photolithographic process and an etching process, to expose thereby the surface of the n-AlₓGa₁₋ₓN layer 12 at a region other than the formation region of the gate insulating film 17 and the gate electrode 16. The etching process may be accomplished for instance by RIE (Reactive Ion Etching) or ICP (Inductively Coupled Plasma)-RIE. Other than a polycrystalline silicon film doped with an n-type impurity, a metal film of gold (Au), platinum (Pt) of nickel (Ni), or an alloy film or stacked film of the foregoing, may also be used as the gate electrode 16.

Next, the pair of source electrodes 18 that are in ohmic contact with the n⁺-type source region 15 and the p⁺-type well region 14 formed in the n-AlₓGa₁₋ₓN layer 12, is selectively formed on the surface of the exposed n-AlₓGa₁₋ₓN layer 12, at regions flanking the gate electrode 16 while spaced apart from the latter. For instance, a stacked metal film comprising Ti/Al resulting from sequentially stacking titanium (Ti) and aluminum (Al), can be used as the source electrodes 18. The configuration of the source electrodes 18 is not limited thereto, and various types of metallic material can be used herein, so long as the resulting conductor film has an ohmic junction, or a low-resistance junction close to that of an ohmic junction, with the n⁺-type source region 15 and the p⁺-type well region 14. A lift-off method or selective growth method can be used to form the source electrodes 18.

Next, the drain electrode 19, comprising a stacked metal film, for instance Ti/Al, is formed on the rear surface of the n-GaN substrate 11, on the side opposite that where the source electrodes 18 are formed on the n-AlₓGa₁₋ₓN layer 12. Dicing is performed thereafter through element separation, as a result of which there is produced the semiconductor device 1 illustrated in FIG. 1.

In Embodiment 1 of the present invention described above, the first cap layer 2a comprising Al_{y}Ga_{1-y}N, having a lattice constant smaller than that of the material of the n-AlₓGa₁₋ₓN layer 12, and the second cap layer 2b comprising Al_{z}Ga_{1-z}N, having a greater lattice constant than that of Al_{y}Ga_{1-y}N, are sequentially grown epitaxially, as protective films, on the n-AlₓGa₁₋ₓN layer 12. As a result, this allows relieving strain in the first cap layer 2a that is sandwiched between the n-AlₓGa₁₋ₓN layer 12 and the second cap layer 2b. The thickness of the first cap layer 2a can be made accordingly greater than the thickness at which the cap layer functions as a protective film towards activation annealing, being a thickness greater than at least a room-temperature critical thickness, of a single cap layer in a case where the second cap layer 2b is not provided. Therefore, a surface protective effect towards the n-AlₓGa₁₋ₓN layer 12 can be preserved also during activation annealing, where the thermal treatment temperature is high, while suppressing nitrogen loss from the n-AlₓGa₁₋ₓN layer 12. Therefore, activation annealing can be performed stably and effectively in the production of the semiconductor device, while enhancing the operating characteristics of the semiconductor device 1 that is produced.

In Embodiment 1 described above, impurities are ion-implanted after formation of the first cap layer 2a and the second cap layer 2b on the n-AlₓGa₁₋ₓN layer 12; this allows reducing as a result the number of processes, such as post-processing after ion implantation, as compared with an instance where the n-AlₓGa₁₋ₓN layer 12 is ion-implanted before formation of the first cap layer 2a and the second cap layer 2b, and allows suppressing damage, caused by the ion implantation method, of the surface of the n-AlₓGa₁₋ₓN layer 12, while dispensing with the need for re-growing the surface of the n-AlₓGa₁₋ₓN layer 12 after ion implantation. Therefore, a semiconductor device can be produced more stably than in conventional instances, without increasing the number of processes, while the characteristics of the semiconductor device 1 can be yet further enhanced.

### Embodiment 2

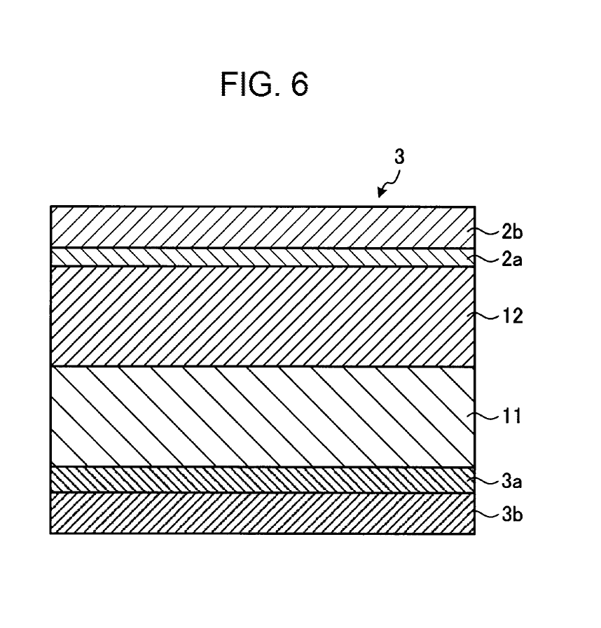

A method for producing a semiconductor device according to Embodiment 2 of the present invention will be explained next. FIG. 6 is a cross-sectional diagram illustrating a substrate to be processed 3 subjected to a thermal treatment according to Embodiment 2.

Embodiment 2 differs from Embodiment 1 in that now the first cap layer 2a and the second cap layer 2b are sequentially formed, for instance by MOCVD, on the surface of the n-AlₓGa₁₋ₓN layer 12, and thereafter, a first cap layer 3a comprising Al_{y}Ga_{1-y}N and a second cap layer 3b comprising Al_{z}Ga_{1-z}N are sequentially formed, for instance by MOCVD, as a rear surface protective film, on the rear surface of the n-GaN substrate 11, on the side opposite that of the stacking face of the n-GaN substrate 11 on which the n-AlₓGa₁₋ₓN layer 12 is formed. That is, the substrate to be processed 3 is formed in which the first cap layers 2a, 3a and the second cap layers 2b, 3b are respectively formed on the surface of the n-AlₓGa₁₋ₓN layer 12 and the rear surface of the n-GaN substrate 11.

Impurities are thereafter ion-implanted, in accordance with an ion implantation method, in the substrate to be processed 3, in the same way as in Embodiment 1, so that, as a result, impurities are ion-implanted in the n-AlₓGa₁₋ₓN layer 12, the first cap layer 2a and the second cap layer 2b. Thereafter, activation annealing at high temperature is performed to activate thereby the impurities that have been ion-implanted. Other features of the method for producing a semiconductor device and of the produced semiconductor device are identical to those of Embodiment 1, and will not be explained again.

In the method for producing a semiconductor device according to Embodiment 2, activation annealing is performed after formation of the first cap layer 2a and the second cap layer 2b, as is the case in Embodiment 1, and hence the same effect as in Embodiment 1 can be achieved herein. Further, activation annealing is performed in a state where the first cap layer 3a and the second cap layer 3b are formed also on the rear surface of the n-GaN substrate 11. As a result, this allows activating the impurities having been doped, while suppressing occurrence of nitrogen loss from the n-GaN substrate 11 due to the high-temperature thermal treatment. It becomes therefore possible to further enhance the characteristics of the semiconductor device that is produced using the substrate to be processed 3.

Embodiments of the present invention have been explained in specific terms above, but the present invention is not limited to the embodiments described above, and may accommodate all manner of variations that are based on the technical concept of the present invention. For instance, the numerical values in the embodiments above are merely exemplary in character, and other numerical values may be resorted to, as needed.

In the embodiments described above, for instance, the n-AlₓGa₁₋ₓN layer 12 is doped with impurities by ion implantation, but the impurity doping method is not necessarily limited to ion implantation, and other impurity doping methods may be resorted to that involve, for instance, introducing impurities into the growth atmosphere during epitaxial growth of the n-AlₓGa₁₋ₓN layer 12.

In the embodiments described above, instances have been explained in which the high-temperature thermal treatment according to the present invention is used in the activation annealing that is performed after impurity doping, specifically activation annealing for activating the impurities with which the n-AlₓGa₁₋ₓN layer 12 has been doped, but the thermal treatment is not necessarily limited to activation annealing, and the thermal treatment of the present invention may be used in any other instances of thermal treatment that is performed on semiconductor layers, for example annealing after formation of a gate oxide film (Post-Deposition Anneal: PDA), or metal sintering treatments.

In the embodiments explained above, an instance of a vertical-type MOSFET has been explained, but the semiconductor device is not necessarily limited to a vertical-type MOSFET, and may be some other semiconductor device, of various kinds, for instance a transistor, diode, power source circuit inverter or the like, produced in accordance with a production method that has a thermal treatment step.

In Embodiments 1 and 2 above, the protective film that is stacked on the surface of the n-AlₓGa₁₋ₓN layer 12 or the rear surface of the n-GaN substrate 11 has two layers, namely the first cap layer 2a (3a) and the second cap layer 2b (3b), but the protective film is not necessarily limited to having two layers. Specifically, a configuration is possible wherein multiple sets of the first cap layer 2a (3a) and the second cap layer 2b (3b) are respectively stacked on the surface of the n-AlₓGa₁₋ₓN layer 12 or the rear surface of the n-GaN substrate 11, to yield thereby respective protective films of the front and rear surfaces. Preferably, the first cap layer 2a (3a) and the second cap layer 2b (3b) are sequentially formed without being exposed to the atmospheric air, in a reduced-pressure atmosphere and at a heating temperature, as described above, from the viewpoint of suppressing cracks and preventing surface contamination.

In Embodiment 2 above, the first cap layer 2a and the second cap layer 2b are sequentially formed on the surface of the n-AlₓGa₁₋ₓN layer 12, and thereafter the first cap layer 3a and the second cap layer 3b are sequentially formed on the n-GaN substrate 11. However, the formation sequence is not necessarily limited thereto, and the first cap layer 3a and the second cap layer 3b may be sequentially formed on the n-GaN substrate 11, after which the first cap layer 2a and the second cap layer 2b are sequentially formed on the surface of the n-AlₓGa₁₋ₓN layer 12. Further, the first cap layer 2a and the first cap layer 3a may be formed simultaneously, after which the second cap layer 2b and the second cap layer 3b are formed simultaneously, or the first cap layer 2a, the first cap layer 3a, the second cap layer 2b and the second cap layer 3b may be formed in mutually separate processes. Alternatively, the first cap layer 2a and the first cap layer 3a may be formed simultaneously, followed by formation of the second cap layer 2b and the second cap layer 3b in separate processes, or the first cap layer 2a and the first cap layer 3a may be formed in separate processes, followed by simultaneous formation of the second cap layer 2b and the second cap layer 3b.

### INDUSTRIAL APPLICABILITY

The present invention can be suitably used in cases where a thermal treatment step is involved in the production of a semiconductor device that utilizes a wide band gap semiconductor, for instance gallium nitride (GaN)-based semiconductor.

### EXPLANATION OF REFERENCE NUMERALS

1 semiconductor device

2, 3 substrate to be processed

2a, 3a first cap layer

2b, 3b second cap layer

11 n-type gallium nitride (n-GaN) substrate

12 n-AlₓGa₁₋ₓN layer

13 p-type well region

14 p⁺-type well region

15 n⁺-type source region

16 gate electrode

17 gate insulating film

18 source electrode

19 drain electrode

What is claimed is:

1. A method for producing a semiconductor device having a nitride-based semiconductor layer, the method comprising, in the order recited:
forming a first nitride-based semiconductor layer of AlₓGa₁₋ₓN on a base;
forming a second nitride-based semiconductor layer of Al_{y}Ga_{1-y}N on the first nitride-based semiconductor layer;
forming a third nitride-based semiconductor layer of Al_{z}Ga_{1-z}N on the second nitride-based semiconductor layer;
introducing an impurity using ion implantation into the first nitride-based semiconductor layer, the second nitride-based semiconductor layer and the third nitride-based semiconductor layer; and
thermally treating, after ion implantation, the first nitride-based semiconductor layer, the second nitride-based semiconductor layer and the third nitride-based semiconductor layer,
wherein the first, second, and third nitride-based semiconductor layers have respective Al composition ratios x, y, and z, and the Al composition ratio y of the second nitride-based semiconductor layer is higher than the Al composition ratio x of the first nitride-based semiconductor layer, and higher than the Al composition ratio z of the third nitride-based semiconductor layer.

2. The method for producing a semiconductor device according to claim 1, wherein the first nitride-based semiconductor layer is AlₓGa₁₋ₓN (0≦x<0.5).

3. The method for producing a semiconductor device according to claim 2, wherein the first nitride-based semiconductor layer is AlₓGa₁₋ₓN (0≦x<0.2).

4. The method for producing a semiconductor device according to claim 1, wherein the second nitride-based semiconductor layer is Al_{y}Ga_{1-y}N (0.5≦y≦1).

5. The method for producing a semiconductor device according to claim 4, wherein the second nitride-based semiconductor layer is Al_{y}Ga_{1-y}N (0.8≦y≦1).

6. The method for producing a semiconductor device according to claim 1, wherein the third nitride-based semiconductor layer is Al_{z}Ga_{1-z}N (0≦z<0.5).

7. The method for producing a semiconductor device according to claim 6, wherein the third nitride-based semiconductor layer is Al_{z}Ga_{1-z}N (0≦z<0.2).

8. The method for producing a semiconductor device according to claim 1, wherein the base has a substrate formed of gallium nitride.

9. The method for producing a semiconductor device according to claim 1, wherein the third nitride-based semiconductor layer has a thickness that is greater than that of the second nitride-based semiconductor layer.

10. The method for producing a semiconductor device according to claim 1, wherein the second nitride-based semiconductor layer has a thickness and a room temperature critical thickness determined for a semiconductor device not having a third nitride-based semiconductor layer, and wherein the thickness of the second nitride-based semiconductor is greater than the room-temperature critical thickness of the second nitride-based semiconductor layer.

11. The method for producing a semiconductor device according to claim 1, wherein the third nitride-based semiconductor layer has a thickness that is 50 nm or greater.

12. The method for producing a semiconductor device according to claim 1, wherein forming the first nitride-based semiconductor layer, the second nitride-based semiconductor layer and the third nitride-based semiconductor layer is accomplished using metal-organic chemical vapor deposition.

13. The method for producing a semiconductor device according to claim 1, wherein the impurity introduced using ion implantation includes at least one element selected from the group consisting of magnesium, zinc and beryllium.

14. The method for producing a semiconductor device according to claim 1, wherein thermally treating takes place at a temperature ranging from 800° C. to 2000° C.

15. The method for producing a semiconductor device according to claim 1, further comprising removing, after thermally treating, at least part of the second nitride-based semiconductor layer and the third nitride-based semiconductor layer.

16. The method for producing a semiconductor device according to claim 15, wherein removing the second nitride-based semiconductor layer is accomplished by wet etching.

17. The method for producing a semiconductor device according to claim 16, wherein removing the third nitride-based semiconductor layer is accomplished by dry etching.

18. The method for producing a semiconductor device according to claim 15, wherein removing the third nitride-based semiconductor layer is accomplished by dry etching.

19. A semiconductor device, which is produced on the basis of the method for producing a semiconductor device according to claim 1.
